(19) United States
(12) Patent Application Publication
(10) Pub. No.: US 2017/0170424 A1
(43) Pub. Date: Jun. 15, 2017

(54) ELECTROLUMINESCENT DEVICE AND ITS MANUFACTURING METHOD, DISPLAY SUBSTRATE, DISPLAY UNIT

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventors: Haidong WU, Beijing (CN); Minghua XUAN, Beijing (CN); Weilin LAI, Beijing (CN); Qun MA, Beijing (CN)

(21) Appl. No.: 15/126,401

(22) PCT Filed: Nov. 6, 2015
(86) PCT No.: PCT/CN2015/094044

§ 371 Date: Sep. 15, 2016

(30) Foreign Application Priority Data
May 26, 2015 (CN) 201510276606.2

(51) Int. Cl. H01L 51/52; H01L 51/56; H01L 51/00; H01L 51/50

(52) U.S. Cl. CPC H01L 51/5234; H01L 51/5072; H01L 51/5012; H01L 51/5056; H01L 51/5218; H01L 51/5088; H01L 51/5096; H01L 51/5092; H01L 51/56; H01L 51/0021; H01L 2251/301; H01L 2251/308; H01L 2251/306; H01L 2251/558

(57) ABSTRACT

An electroluminescent device and its manufacturing method, a display substrate and a display device are disclosed. The electroluminescent device includes a substrate and a cathode layer-disposed on the substrate; the cathode layer is disposed at an emitting side of the electroluminescent device, the cathode layer comprises a transparent electrode layer and a metal electrode layer, and the transparent electrode layer-and the metal electrode layer are stacked together. The surface resistance of the cathode, the driving voltage and energy consumption of the electroluminescent device are remarkably reduced.

### BACKGROUND

The embodiment of present invention relates to an electroluminescent device and its manufacturing method, a display substrate and a display unit.

The OLED devices of an active matrix organic light emitting diode (AM-OLED) display emit light mainly from a cathode side, that is to say, as shown in FIG. 1, an anode 040 and a cathode 020 are provided at both sides of the functional layer 030 respectively, when an external electric field above a certain threshold is applied to the anode 040 and the cathode 020, the holes and electrons are injected into the luminescent layer of the functional layer 030 from the anode 040 and the cathode 020, respectively, then radiative recombination takes place and thus illumination happens, light emits out from a side of the cathode 020, thereby the display is realized.

To improve the efficiency of the electron injection from the cathode into the functional layer so as to increase the luminescence efficiency of the OLED devices, the cathode usually employs an elemental metal and/or alloy material having a lower work function. However, due to the low light transmittance of the elemental metal and/or alloy material, the cathode should be made relatively thin so as to increase the overall light emitting efficiency of the OLED device. However, when a thickness of the cathode is reduced, its surface resistance Rs (Rs=p/t, p represents resistivity, and t represents thickness) would increase remarkably, thus results in an increased driving voltage and energy consumption.

### SUMMARY

Embodiments of the present invention provide an electroluminescent device, comprising: a substrate and a cathode layer disposed on the substrate; wherein the cathode layer is disposed at an emitting side of the electroluminescent device, the cathode layer comprising a transparent electrode layer and a metal electrode layer, and the transparent electrode layer and the metal electrode layer are stacked together.

In one embodiment of the present invention, for example, the electroluminescent device further comprising a functional layer; wherein the metal electrode layer is disposed between the transparent electrode layer and the functional layer; and in a direction away from the cathode layer, the functional layer sequentially comprises an electron transport layer, a luminescent layer and a hole transport layer.

In one embodiment of the present invention, for example, the cathode layer is disposed at a side of the functional layer away from the substrate.

In one embodiment of the present invention, for example, the electroluminescent device further comprising an anode layer located at a side of the functional layer close to the substrate.

In one embodiment of the present invention, for example, the functional layer further comprises: at least one of a hole injection layer, an electron blocking layer and an electron injection layer; wherein the hole injection layer is disposed between the anode layer and the hole transport layer; the electron blocking layer is disposed between the hole transport layer and the luminescent layer; the electron injection layer is disposed between the electron transport layer and the cathode layer.

In one embodiment of the present invention, for example, the electroluminescent device further comprises a reflective metal layer at a side of the anode layer close to the substrate.

In one embodiment of the present invention, for example, a material of the metal electrode layer is selected from at least one of Mg, Ag, Li and Al.

In one embodiment of the present invention, for example, a material of the transparent electrode layer is selected from at least one of ITO, IZO and FTO.

In one embodiment of the present invention, for example, a thickness of the metal electrode layer is from 2 nm to 15 nm; a thickness of the transparent electrode layer is from 5 nm to 40 nm.

Embodiments of the present invention provide a method for manufacturing an electroluminescent device, comprising: forming a cathode layer on a substrate; wherein the resultant cathode layer is located at an emitting side of the electroluminescent device, the cathode layer comprising a transparent electrode layer and a metal electrode layer, and the transparent electrode layer and the metal electrode layer are stacked together.

In one embodiment of the present invention, for example, the method further comprising, before forming the cathode layer on the substrate: forming a functional layer on the substrate; wherein, in a direction away from the cathode layer, the functional layer sequentially comprises an electron transport layer, a luminescent layer and a hole transport layer; and forming the cathode layer on the substrate comprising: forming a metal electrode layer on the resultant functional layer; forming a transparent electrode layer on the resultant metal electrode layer by a low-temperature film-forming process; wherein the film-forming temperature of the low-temperature film-forming process is less than or equal to 100° C.

In one embodiment of the present invention, for example, the low-temperature film-forming process comprises at least one of an anion beams sputtering process, a low-temperature chemical vapor deposition process.

In one embodiment of the present invention, for example, the method further comprising, before forming the functional layer on the substrate: forming an anode layer on the substrate.

In one embodiment of the present invention, for example, the resultant functional layer further comprises: at least one of a hole injection layer, an electron blocking layer and an electron injection layer; wherein the manufacturing method further comprises forming the hole injection layer after forming the anode layer and before forming the hole transport layer; or the manufacturing method further comprises forming the electron blocking layer after forming the hole transport layer and before forming the luminescent layer; or the manufacturing method further comprises forming the electron injection layer after forming the electron transport layer and before forming the cathode layer.

In one embodiment of the present invention, for example, the method further comprising, before forming the anode layer on the substrate: forming a reflective metal layer on the substrate.

In one embodiment of the present invention, for example, a thickness of the resultant metal electrode layer is from 2 nm to 15 nm; a thickness of the resultant transparent electrode layer is from 5 nm to 40 nm.

Embodiments of the present invention provide a display substrate comprising the above described electroluminescent device.

Embodiments of the present invention provide a method of manufacturing a display substrate, comprising forming an electroluminescent device on a substrate, wherein the electroluminescent device is manufactured by the above described method for manufacturing an electroluminescent device.

Embodiments of the present invention provide a display device comprising the above described display substrate.

### BRIEF DESCRIPTION OF THE DRAWINGS

In order to clearly illustrate the technical solution of the embodiments of the disclosure, the drawings of the embodiments will be briefly described in the following, it is obvious that the described drawings are only related to some embodiments of the disclosure and thus are not limitative of the disclosure.

FIG. 1 is a sectional structural diagram of a conventional OLED device;

FIG. 2 is a sectional structural diagram of an electroluminescent device provided by an embodiment of present invention;

FIG. 3 is a sectional structural diagram of an electroluminescent device provided by another embodiment of present invention;

FIG. 4 is a sectional structural diagram of an electroluminescent device provided by another embodiment of present invention;

FIG. 5 is a sectional structural diagram of an electroluminescent device provided by another embodiment of present invention;

FIG. 6 is a principle diagram showing a light path of the electroluminescent device as shown in FIG. 5;

FIG. 7 is a schematic diagram showing a fabrication process of an electroluminescent device provided by an embodiment of present invention.

### REFERENCE NUMERALS

01-electroluminescent device; 10-substrate; 20-cathode layer; 22-metal electrode layer; 21-transparent electrode layer; 30-functional layer; 31-electron transport layer; 32-luminescent layer; 33-hole transport layer; 34-hole injection layer; 35-electron blocking layer; 36-electron injection layer; 40-anode layer; 50-reflective metal layer.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at least one. The phrases “connect”, “connected”, etc., are not intended to define a physical connection or mechanical connection, but may include an electrical connection, directly or indirectly.

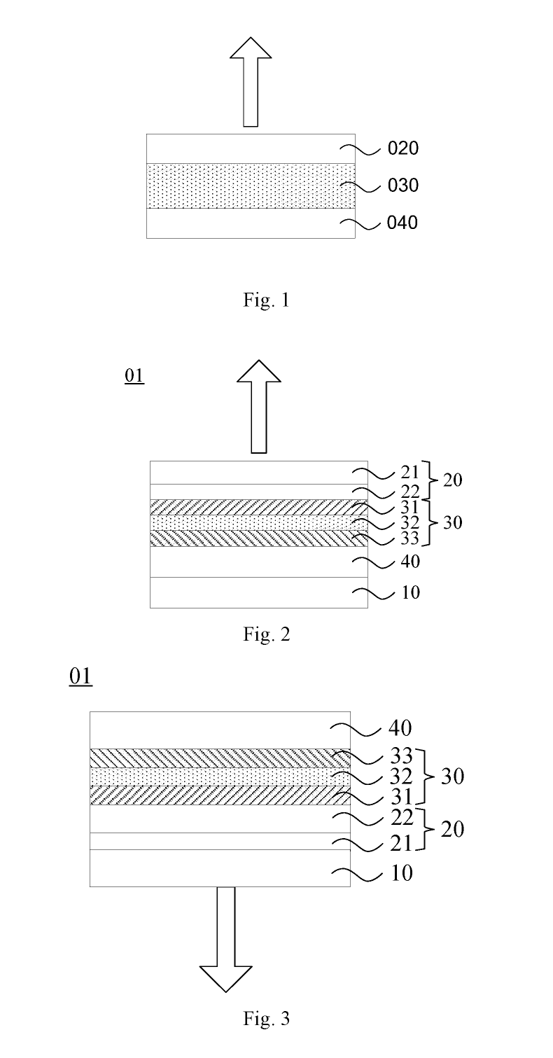

The embodiment of present invention provides an electroluminescent device 01 which, as shown in FIG. 2, comprises a substrate 10 and a cathode layer 20 disposed on the substrate 10; wherein the cathode layer 20 is disposed at an emitting side of the electroluminescent device 01, and the cathode layer 20 comprises a transparent electrode layer 21 and a metal electrode layer 22.

It should be noted that, firstly, the above mentioned substrate 10 may be a glass substrate and the like, or may be a substrate formed with TFT array, no specific restriction is made in the embodiments of present invention.

The electroluminescent device 01 may be an organic light-emitting diode device (OLED), for example.

Secondly, the transparent electrode layer 21 can be composed of at least one material of indium tin oxide (ITO), indium zinc oxide (IZO) and fluorine-doped tin oxide (FTO).

The metal electrode layer 22 may be composed of at least one metal material of Mg, Ag, Li, Al. That is to say, it can be a simple substance of the above metal elements, or can also be a metal alloy composed of two or more of the above metal elements.

Thirdly, the cathode layer 20 is disposed at an emitting side of the electroluminescent device 01, as shown in FIG. 2, when the electroluminescent device 01 illuminates in a top-emitting mode, the light emits upward from an upper side of the cathode layer 20 with respect to the substrate 10 (as indicated by the direction of the arrow in the drawings); as shown in FIG. 3, when the electroluminescent device 01 illuminates in a bottom-emitting mode, the light emits from a lower side of the cathode layer 20 with respect to the substrate 10.

In consideration of the above electroluminescent device 01 being applied to a display unit, for example an AM-OLED, each device is wired to the thin film transistors (TFT) of the array substrate, thereby through independent control of the addressing of corresponding TFT, it is possible to independently and selectively regulate each of the pixels, and to achieve a colorization display of the OLED easily. However, because the TFTs arranged on the array substrate in an array configuration and the signal lines connected to the TFTs, such as the grid lines, the data lines etc., are opaque, thus alternatively, as shown in FIG. 2, the electroluminescent device 01 provided by the embodiments of present invention illuminates in a top-emitting mode, so that the light emitted through the electron-hole recombination can emit out from the illuminating device 01 as effectively as possible.

Of course, the above electroluminescent device 01 provided by the embodiments of present invention may also be a bottom-emitting type, in which the locations of the cathode layer 20 with respect to the array substrate is different from that of the top-emitting type, and the light exiting efficiency can also be improved.

In the above electroluminescent device 01 provided by the embodiment of present invention, since the cathode layer 20 comprises the transparent electrode layer 21 and the metal electrode layer 22, that is, the two layers 21 and 22 contact with each other, thus when the electroluminescent device 01 is in use, the two electrode layers are electrically connected into a circuit in parallel, thereby it is possible to decrease the overall surface resistance of the cathode layer 20 comprising the two electrode layers, and the driving voltage of the devices and the energy consumption are reduced, too; therefore, the metal electrode layer 22 of the embodiment of present invention can be made thinner as compared with the independent metal cathode used in the existing OLEDs.

For example, a thickness of the transparent electrode layer 21 may be from 5 nm to 40 nm; a thickness of the metal electrode layer 22 may be from 2 nm to 15 nm; that is to say, the cathode layer 20 comprising the metal electrode layer 22 and the transparent electrode layer 21, can have an overall thickness of from 7 nm to 55 nm.

The above thickness ranges could ensure a higher overall light transmittance of the cathode layer 20 comprising the transparent electrode layer 21 and the metal electrode layer 22 while reducing its overall surface resistance.

Further, as shown in FIG. 2, the electroluminescent device 01 may further comprise a functional layer 30; wherein the metal electrode layer 22 is disposed between the transparent electrode layer 21 and the functional layer 30; in a direction away from the cathode layer 20, such a functional layer 30 may sequentially comprise for example an electron transport layer 31, a luminescent layer 32 and a hole transport layer 33.

It should be noted that, firstly, the functional layer 30 can be located below the cathode layer 20 with respect to the substrate 10 as shown in FIG. 2, that is to say, the electroluminescent device 01 illuminates in a top-emitting mode; with such a light-emitting mode, the light generated by the radiative recombination of the electrons and holes passes through the metal electrode layer 22, the transparent electrode layer 21 sequentially and emits out upward, thereby realizing the display.

Of course, the functional layer 30 can also be located above the cathode layer 20 with respect to the substrate 10, that is to say, the electroluminescent device 01 illuminates in a bottom-emitting mode; as shown in FIG. 3, in such a light-emitting mode, the light generated by the radiative recombination of the electrons and holes passes through the metal electrode layer 22, the transparent electrode layer 21 sequentially and emits out from the substrate 10, thereby realizing the display.

Secondly, for example, the electron transport layer (ETL) 31 can be composed of oligothiophene derivatives, triazole derivatives, quinoxaline derivatives, perfluorinated aromatic compounds etc.; the luminescent layer (EL) can be composed of Alq_{3 (}8-hydroxyquinoline aluminum) and its derivatives; the hole transport layer (HTL) 33 can be composed of triphenylamine derivative and certain polymers.

Since the metal electrode layer 22 is located between the transparent electrode layer 21 and the functional layer 30, that is to say, the transparent electrode layer 21 of a higher light transmittance is located at the emitting side of the metal electrode layer 22, thus when the devices are in use, the electrons inspired from the metal cathode layer 21 need not to pass through the transparent electrode layer firstly, but can directly inject into the functional layer 30 and then recombine with the holes to illuminate, thereby the recombination rate of the electron-hole is not influenced.

Further, as shown in FIG. 2, for example, the cathode layer 20 is located above the functional layer 30 with respect to the substrate 10. Since the cathode layer 20 is located at an emitting side of the electroluminescent device 01, the electroluminescent device 01 illuminates in a top-emitting mode.

Further, as shown in FIG. 2, the electroluminescent device 01 further comprises an anode layer 40 below the functional layer 30. The anode layer 40 may comprise ITO, IZO and FTO with a higher work function, so as to increase the excitation rate of the holes.

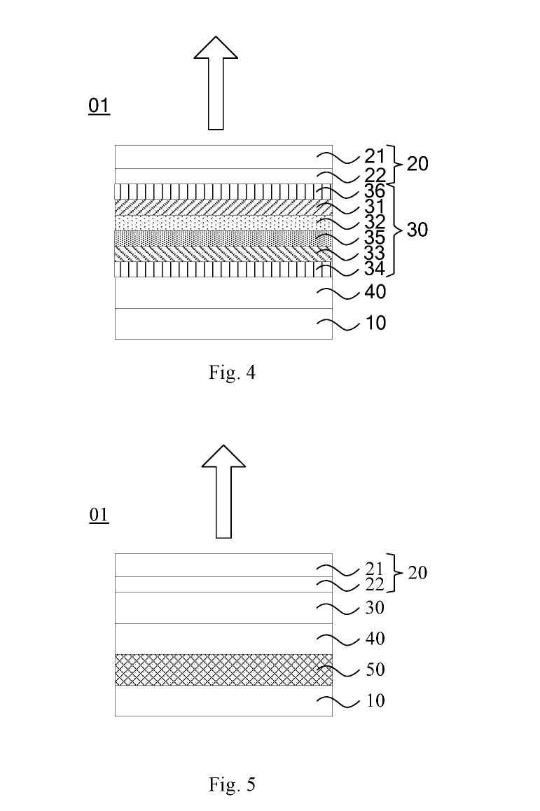

To further improve the efficiency of electrons and holes injecting into the functional layer 30, as shown in FIG. 4, the functional layer 30 may further comprise at least one of the hole injection layer (HIL) 34, the electron blocking layer (EBL) 35 and the electron injection layer (EIL) 36.

The hole injection layer is disposed between the anode layer 40 and the hole transport layer 33, playing a role of improving the injection efficiency of the holes inspired from the anode layer 40 into the hole transport layer 33; for example, the hole injection layer 34 can be composed of CuPc (Copper(II) phthalocyanine).

The electron injection layer 36 is disposed between the cathode layer 20 and the electron transport layer 31, and functions to improve the injection efficiency of the electrons inspired from the cathode layer 20 into the electron transport layer 31; for example, the electron injection layer 36 can be composed of Liq (8-hydroxyquinoline lithium).

The electron blocking layer 35 is disposed between the hole transport layer 33 and the luminescent layer 32, and functions to block the electrons from transmitting over the luminescent layer 32 and recombining radiatively with the holes of the hole transport layer 33, thus decreasing luminescence efficiency; for example, the electron blocking layer 35 can be composed of TFB (poly-(9,9-Di-n-octyl phthalate-fluorene-co-N-(4-benzyl)aniline)), TAPC (1,1-Bis-(4-methylphenyl)-aminophenyl)-cyclo-hexane), NPB (N,N′-Diphenyl-N,N′-bis(a-naphthyl)-1,1′-biphenyl-4,4′-diamine) and similar organic materials.

It should be noted that, for clarity, FIG. 4 illustrates by way of example the case in which the functional layer 30 comprises the above mentioned six kinds of structural layers, i.e., HTL, EL, ETL, HIL, EBL and EIL.

The three layers, i.e., the HTL layer, the EL layer and the ETL layer, are essential layers required for achieving the electroluminescence; the HIL layer, the EBL layer and the EIL layer are layers required for further improving the luminescence efficiency, in addition to the above HTL layer, EL layer and ETL layer, the functional layer 30 can only comprise at least one of the HIL layer, EBL layer and EIL layer, no specific restriction is made herein.

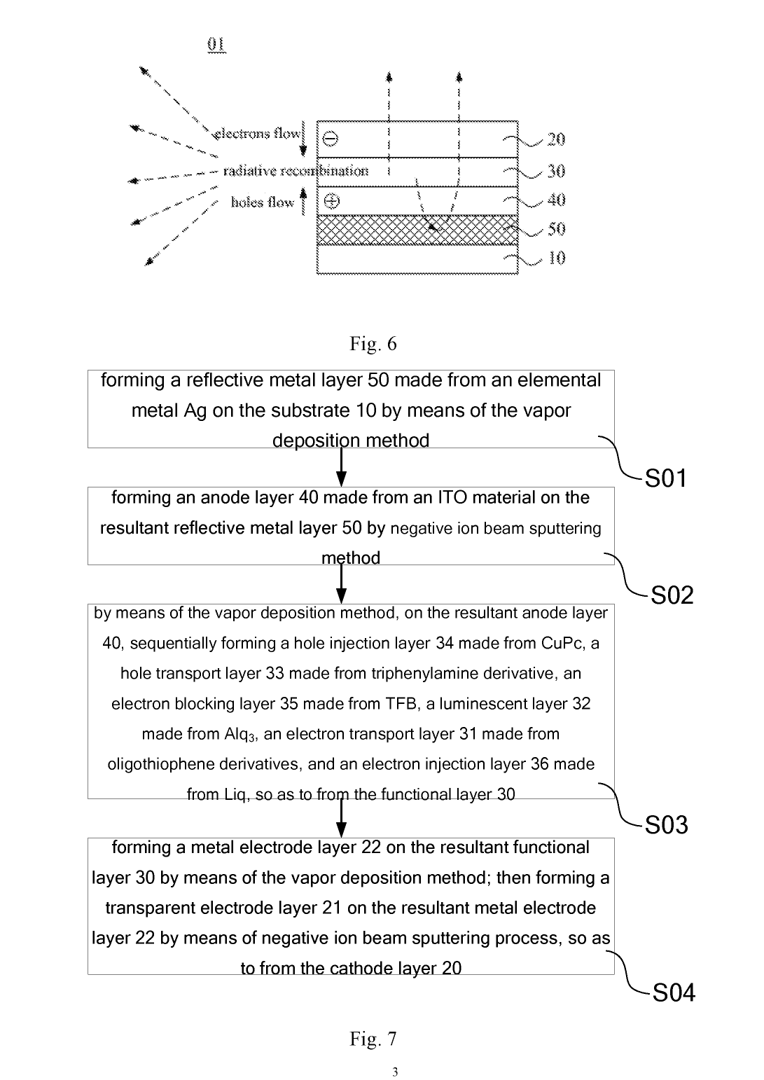

Further, as shown in FIG. 5, the electroluminescent device 01 may further comprise a reflective metal layer 50 disposed below the anode layer 40. Since the electroluminescent device 01 illuminates in a top-emitting mode, part of the light generated through the radiative recombination of the electrons and holes would emits out from the top cathode layer 20, while the other part of the light emits out from the bottom anode layer 40, and since the light emits out from the bottom anode layer 40 can not be effectively used for displaying, which depresses the luminous efficiency. Therefore, to improve the luminous efficiency of the devices, the reflective metal layer 50 is provided between the substrate 10 and the anode layer 40. The light path is illustrated in FIG. 6. The light emitting out from the anode layer 40 is reflected by the reflective metal layer 50, and then emits upwards from the cathode layer 20, and finally the luminous efficiency of the electroluminescent device 01 is improved.

The embodiment of present invention also provides a method for manufacturing the above mentioned electroluminescent device 01, the manufacturing method comprises forming a cathode layer 20 on a substrate 10; wherein the resultant cathode layer 20 is disposed at an emitting side of the electroluminescent device 01, and the cathode layer 20 comprises a transparent electrode layer 21 and a metal electrode layer 22.

Since the resultant cathode layer 20 comprises the transparent electrode layer 21 and the metal electrode layer 22, that is, the two layers 21 and 22 contact with each other, thus when the electroluminescent device 01 is in use, the two electrode layers are electrically connected into a circuit in parallel, thereby it is possible to decrease the overall surface resistance of the cathode layer 20 comprising the two electrode layers, and the driving voltage and the energy consumption are reduced; therefore, a thickness of the metal electrode layer 22 of the embodiment of present invention can be reduced as compared with that of the independent metal cathode used in the existing OLEDs.

For example, the thickness of the resultant transparent electrode layer 21 may be from 5 nm to 40 nm; the thickness of the resultant metal electrode layer 22 may be from 2 nm to 15 nm; that is to say, the cathode layer 20 comprising the metal electrode layer 22 and the transparent electrode layer 21, may have an overall thickness of from 7 nm to 55 nm.

Further, before forming the cathode layer 20 on the substrate 10, the above manufacturing method further comprises forming the functional layer 30 on the substrate 10; wherein, in a direction away from the cathode layer 20, the resultant functional layer 30 sequentially comprises an electron transport layer 31, a luminescent layer 32 and a hole transport layer 33.

In consideration of the above electroluminescent device 01, which comprises a structure of the above cathode layer 20, being applied to a display unit, for example an AM-OLED, each device is wired to the thin film transistors (TFT) of the array substrate, thereby through independent control of the addressing of corresponding TFT, it is possible to independently and selectively regulate each of the pixels, and to achieve a colorization display of the OLED easily; however, since the TFTs arranged on the array substrate in an array configuration and the signal lines connected to the TFTs, such as the grid lines, the data lines etc., are opaque, thus according to an alternative embodiment of the present invention, taking the light-emitting mode shown in FIG. 2 as an example, the electroluminescent device 01 formed through the above manufacturing method illuminates in a top-emitting mode, that is, a functional layer 30 is formed on the substrate 10 in advance, then the above cathode layer 20 is formed, so that the light emitted through recombination of the electrons and holes can emit out from the illuminating device 01 as effectively as possible. Of course, the above electroluminescent device 01 provided by the embodiment of present invention may also be a bottom-emitting type, in which the locations of the cathode layer 20 with respect to the array substrate is different from that of the top-emitting type, and the light exiting efficiency can also be improved.

For example, to form a cathode layer 20 on the substrate, for example, forming a metal electrode layer 22 on the resultant functional layer 30; forming a transparent electrode layer 21 on the resultant metal electrode layer 22 by a low-temperature film-forming process; wherein the film-forming temperature of the low-temperature film-forming process is less than or equal to 100° C.

It should be noted that, firstly, since the resultant functional layer 30 is formed with a metal electrode layer in advance and then with a transparent electrode layer 21, Since the metal electrode layer 22 is located between the transparent electrode layer 21 and the resultant functional layer 30, that is to say, the transparent electrode layer 21 of a higher light transmittance is located at the emitting side of the metal electrode layer 22, thus when the devices are in use, the electrons need not to pass through the transparent electrode layer before being injected into the functional layer 30, but the electrons inspired from the metal cathode layer 21 can directly inject into the functional layer 30 and then recombine with the holes to illuminate, thereby the recombination rate of the electron-hole is not influenced.

Secondly, since the materials for constituting the functional layer 30 are usually organic materials or inorganic semiconductor materials etc., which have a poor heat resistant property, when a conventional high temperature film-forming process is employed for forming the transparent electrode layer 21 on the metal electrode layer 22, such as the vapor deposition process, sputtering process and the like, the metal electrode layer 22 will be harmed by the high temperature; at the same time, the metal electrode layer 22 is usually made from an elemental metal and/or metal alloy and thus has a higher thermal conductivity, thus the heat in film-forming process could conduct from the metal electrode layer 22 to the below functional layer 30, thereby damaging the performance of each layer in the functional layer 30 and influencing the luminescence performance of the electroluminescent device 01.

Therefore, the embodiment of present invention further alternatively employs a low-temperature film-forming process of less than or equal to 100° C. to form a transparent electrode layer 21 on the resultant metal electrode layer 22, it is possible to avoid adverse effect of the high temperature in the film-forming process upon the deposited resultant functional layer 30 and metal electrode layer 22, thus ensuring a stable nature of the devices.

For example, the above mentioned low-temperature film-forming process may comprise at least one of an anion beam sputtering process, a low-temperature chemical vapor deposition process. Wherein the anion beam sputtering process is a novel film-forming technology developed on the basis of the vacuum vapor deposition techniques and ionization techniques. For example, in a case where the transparent electrode layer 21 to be plated is made from ITO materials, the maximal advantage of the anion beam sputtering process is that the material particles to be plated (i.e., the above mentioned ITO materials) are sputtered towards the surface of the substrate (i.e., the above mentioned metal electrode layer 22) in an anion form in an electric field. Because the anion beam is accelerated by the electric field, the particles have a higher kinetic energy and chemical activity, the resultant ITO film has a better compactness and a stronger binding force with the substrate surface. In the above processes, an excessively high film-forming temperature is not necessary, the film-forming can be performed under a low-temperature less than or equal to 100° C. (usually, a temperature of 50° C. is sufficient).

The low-temperature chemical vapor deposition process is vapor phase growth process of a thin-film material, that is, a technology in which one or more of the chemical compound and elementary gas containing film-constituting elements (i.e., the above ITO) is (are) passed into the reaction chamber in which the substrate (i.e., the above mentioned metal electrode layer 22) is placed, then a solid film is deposited on the substrate surface under a low temperature by means of spatial vapor phase chemical reaction.

Further, as shown in FIG. 2, before forming the functional layer 30 on the substrate 10, the manufacturing method may further comprise forming an anode layer 40 on the substrate 10, that is, the resultant electroluminescent device 01 illuminates in a top-emitting mode.

The anode layer 40 may be composed by the ITO, IZO and FTO with a high work function, so as to improve the excitation rate of the holes; the film-forming process may be any conventional spluttering process etc.

Moreover, to further improve the efficiency of the electrons and holes injecting into the functional layer 30 respectively, as shown in FIG. 4, the resultant functional layer 30 may further comprise at least one of the hole injection layer (HIL) 34, the electron blocking layer (EBL) 35 and the electron injection layer (EIL) 36.

Accordingly, the fabrication processes of the above individual layers may be as follows, for example:

After the formation of the anode layer 40 and before the formation of the hole transport layer 33, the above fabrication method ay further comprise forming a hole injection layer 34; it acts to improve the injection efficiency of the holes inspired from the anode layer 40 into the hole transport layer 33; for example, the hole injection layer 34 can be made from CuPc (Copper(II) phthalocyanine) by the vapor deposition process.

After the formation of the hole transport layer 33 and before the formation of the luminescent layer 32, the above manufacturing method may further comprise forming an electron blocking layer 35; it functions to block the electron from transmitting over the luminescent layer 32 and recombining with the holes of the hole transport layer 33, thus decreasing the luminescence efficiency; for example, the electron blocking layer 35 can be composed of TFB (poly-(9,9-Di-n-octyl phthalate-fluorene-co-N-(4-benzyl)aniline)), TAPC (1,1-Bis-(4-methylphenyl)-aminophenyl)-cyclo-hexane), NPB (N,N′-Diphenyl-N,N′-bis(a-naphthyl)-1,1′-biphenyl-4,4′-diamine) and similar organic materials and formed by the vapor deposition process.

After forming the electron transport layer 31 and before forming the cathode layer 20, the above manufacturing method may further comprise forming an electron injection layer 36, it functions to improve the injection efficiency inspired from the cathode layer 20 into the electron transport layer 31; for example, the electron injection layer 36 can be made from Liq (8-hydroxyquinoline lithium) and formed by means of the vapor deposition process.

Further, as shown in FIG. 5, before forming the anode layer 40 on the substrate 10, the above manufacturing method may further comprise forming a reflective metal layer 50 on the substrate 10.

Since the electroluminescent device 01 illuminates in a top-emitting mode, part of the light generated through the radiative recombination of the electrons and holes would emit out from the top cathode layer 20, while the other part of the light emits out from the bottom anode layer 40, and since the light emitting out from the bottom anode layer 40 can not be effectively used for displaying, the luminous efficiency is depressed. Therefore, to improve the luminous efficiency of the devices, the reflective metal layer 50 is provided between the substrate 10 and the anode layer 40. The light path is illustrated in FIG. 6, in which the light emits out from the anode layer 40 can be reflected by the reflective metal layer 50, then is emitted upward again from the cathode layer 20, thus improving the luminous efficiency of the electroluminescent device 01.

As shown in FIG. 7, an embodiment is provided below for a detailed description about the above manufacturing method:

Step S01 forming a reflective metal layer 50 made from an elemental metal Ag on the substrate 10 by means of the vapor deposition method;

Step S02, forming an anode layer 40 made from an ITO material on the resultant reflective metal layer 50;

Step S03, by means of the vapor deposition method, on the resultant anode layer 40, sequentially forming a hole injection layer 34 made from CuPc, a hole transport layer 33 made from triphenylamine derivative, an electron blocking layer 35 made from TFB, a luminescent layer 32 made from Alq₃, an electron transport layer 31 made from oligothiophene derivatives, and an electron injection layer 36 made from Liq, so as to from the functional layer 30;

Step S04, forming a metal electrode layer 22 on the resultant functional layer 30 by means of the vapor deposition method; then forming a transparent electrode layer 21 on the resultant metal electrode layer 22 by means of negative ion beam sputtering process, so as to from the cathode layer 20;

The electroluminescent device 01 is thus formed through the above steps S01 to S04.

The above step S04 can be carried out by means of any one of the following six embodiments:

### Embodiment 1

By means of the vapor deposition method, forming a metal electrode layer 22 made from a Mg-Ag alloy on the resultant functional layer 30, the metal electrode layer 22 has a thickness of 5 nm;

By means of the anion beam spluttering method, forming a transparent electrode layer 21 made from ITO on the resultant metal electrode layer 22, the transparent electrode layer 21 has a thickness of 30 nm.

### Embodiment 2

By means of the vapor deposition method, forming a metal electrode layer 22 made from a Mg-Ag alloy on the resultant functional layer 30, the metal electrode layer 22 has a thickness of 10 nm;

By means of the anion beam spluttering method, forming a transparent electrode layer 21 made from ITO on the resultant metal electrode layer 22, the transparent electrode layer 21 has a thickness of 25 nm.

### Embodiment 3

By means of the vapor deposition method, forming a metal electrode layer 22 made from a Li-Al alloy on the resultant functional layer 30, the metal electrode layer 22 has a thickness of 5 nm;

By means of the anion beam spluttering method, forming a transparent electrode layer 21 made from ITO on the resultant metal electrode layer 22, the transparent electrode layer 21 has a thickness of 40 nm.

### Embodiment 4

By means of the vapor deposition method, forming a metal electrode layer 22 made from a Li-Al alloy on the resultant functional layer 30, the metal electrode layer 22 has a thickness of 10 nm;

By means of the anion beam spluttering method, forming a transparent electrode layer 21 made from ITO on the resultant metal electrode layer 22, the transparent electrode layer 21 has a thickness of 35 nm.

### Embodiment 5

By means of the vapor deposition method, forming a metal electrode layer 22 made from a Mg-Ag alloy on the resultant functional layer 30, the metal electrode layer 22 has a thickness of 2 nm;

By means of the anion beam spluttering method, forming a transparent electrode layer 21 made from IZO on the resultant metal electrode layer 22, the transparent electrode layer 21 has a thickness of 30 nm.

### Embodiment 6

By means of the vapor deposition method, forming a metal electrode layer 22 made from a Li-Al alloy on the resultant functional layer 30, the metal electrode layer 22 has a thickness of 2 nm;

By means of the anion beam spluttering method, forming a transparent electrode layer 21 made from IZO on the resultant metal electrode layer 22, the transparent electrode layer 21 has a thickness of 30 nm.

The embodiment of present invention also provides a display substrate comprising the above electroluminescent device 01 on the substrate 10.

For example, the substrate 10 can be an array substrate formed with a TFT array, for example.

The embodiment of present invention also provides a method for manufacturing the display substrate, the manufacturing method comprises: forming the above electroluminescent device 01 on the substrate 10, the substrate 10 can be an array substrate formed with a TFT array for example.

The embodiment of present invention also provides a display device comprising the above mentioned display substrate.

The above display device can be specifically an OLED panel, an OLED display, an OLED television or an electronic paper, a digital photo frame, a cellphone, a tablet and similar products or parts comprising any display functions.

It should be noted that, all the drawings of the present invention are brief schematic views of the above electroluminescent device and its manufacturing method, in which only the structures associated with the inventive spots are embodied for the purpose of clearly illustrating the present solution, while other structures unrelated to the inventive spots are existing ones, none of or only a part of the other structures is embodied in the drawings

What are described above is related to the illustrative embodiments of the disclosure only and not limitative to the scope of the disclosure; the scopes of the disclosure are defined by the accompanying claims.

The present application claims the priority of the Chinese Patent Application No. 201510276606.2 filed on May 26, 2015, which is incorporated herein by reference as part of the disclosure of the present application.

1. An electroluminescent device, comprising:
a substrate and a cathode layer disposed on the substrate;
wherein the cathode layer is disposed at an emitting side of the electroluminescent device, the cathode layer comprises a transparent electrode layer and a metal electrode layer, and the transparent electrode layer and the metal electrode layer are stacked together.

2. The electroluminescent device according to claim further comprising a functional layer; wherein
the metal electrode layer is disposed between the transparent electrode layer and the functional layer; and
in a direction away from the cathode layer, the functional layer sequentially comprises an electron transport layer, a luminescent layer and a hole transport layer.

3. The electroluminescent device according to claim 2, wherein
the cathode layer is disposed at a side of the functional layer away from the substrate.

4. The electroluminescent device according to claim 3, further comprising an anode layer located at a side of the functional layer close to the substrate.

5. The electroluminescent device according to claim 4, wherein the functional layer further comprises:
at least one of a hole injection layer, an electron blocking layer and an electron injection layer; wherein the hole injection layer is disposed between the anode layer and the hole transport layer;
the electron blocking layer is disposed between the hole transport layer and the luminescent layer; and
the electron injection layer is disposed between the electron transport layer and the cathode layer.

6. The electroluminescent device according to claim 4, further comprising a reflective metal layer located at a side of the anode layer close to the substrate.

7. The electroluminescent device according to claim 1, wherein a material of the metal electrode layer is selected from at least one of Mg, Ag, Li and Al.

8. The electroluminescent device according to claim 1, wherein a material of the transparent electrode layer is selected from at least one of ITO, IZO and FTO.

9. The electroluminescent device according to claim 1, wherein
a thickness of the metal electrode layer is from 2 nm to 15 nm;
a thickness of the transparent electrode layer is from 5 nm to 40 nm.

10. A method for manufacturing an electroluminescent device, comprising:
forming a cathode layer on a substrate; wherein
the obtained cathode layer is located at an emitting side of the electroluminescent device,
and the cathode layer comprises a transparent electrode layer and a metal electrode layer, and the transparent electrode layer and the metal electrode layer are stacked together.

11. The manufacturing method according to claim 10, further comprising, before forming the cathode layer on the substrate:
forming a functional layer on the substrate; wherein, in a direction away from the cathode layer, the functional layer sequentially comprises an electron transport layer, a luminescent layer and a hole transport layer; and
forming the cathode layer on the substrate comprising:
forming a metal electrode layer on the resultant functional layer;
forming a transparent electrode layer on the resultant metal electrode layer by a low-temperature film-forming process; wherein a film-forming temperature of the low-temperature film-forming process is less than or equal to 100° C.

12. The manufacturing method according to claim 11, wherein the low-temperature film-forming process comprises at least one of an anion beams sputtering process, a low-temperature chemical vapor deposition process,

13. The manufacturing method according to claim 11, further comprising, before forming the functional layer on the substrate:
forming an anode layer on the substrate.

14. The manufacturing method according to claim 13, wherein the functional layer further comprises:
at least one of a hole injection layer, an electron blocking layer and an electron injection layer; wherein
the manufacturing method further comprises forming the hole injection layer after forming the anode layer and before forming the hole transport layer; or
the manufacturing method further comprises forming the electron blocking layer after forming the hole transport layer and before forming the luminescent layer; or
the manufacturing method further comprises forming the electron injection layer after forming the electron transport layer and before forming the cathode layer.

15. The manufacturing method according to claim 1 her comprising, before forming the anode layer on the substrate: forming a reflective metal layer on the substrate.

16. The manufacturing method according to claim 10, wherein
a thickness of the resultant metal electrode layer is from 2 nm to 15 nm;
a thickness of the resultant transparent electrode layer is from 5 nm to 40 nm.

17. A display substrate comprising the electroluminescent device according to claim 1.

18. A method of manufacturing a display substrate, comprising forming an electroluminescent device on a substrate, wherein the electroluminescent device is manufactured by the manufacturing method of claim 10.

19. A display device comprising the display substrate according to claim 17.

20. The electroluminescent device according to claim 2, wherein
a thickness of the metal electrode layer is from 2 nm to 15 nm;
a thickness of the transparent electrode layer is from 5 nm to 40 nm.
